(19) United States
(12) Patent Application Publication
(10) Pub. No.: US 2021/0184628 A1
(43) Pub. Date: Jun. 17, 2021

(54) DEVICE AND METHOD FOR DETECTING A PHOTOVOLTAIC MODULE

(71) Applicant: MiaSole Equipment Integration (Fujian) Co., Ltd., Quanzhou, Fujian (CN)

(72) Inventors: Lin Liu, Quanzhou, Fujian (CN); Tao Li, Quanzhou, Fujian (CN); Jing Zeng, Quanzhou, Fujian (CN); Chongyan Lian, Quanzhou, Fujian (CN); Xianyi Huang, Quanzhou, Fujian (CN); Chao Hu, Quanzhou, Fujian (CN); Yi Shu, Quanzhou, Fujian (CN)

(21) Appl. No.: 16/076,306

(22) PCT Filed: Jul. 9, 2018
(86) PCT No.: PCT/CN2018/094946

§ 371 Date: Aug. 7, 2018

(30) Foreign Application Priority Data
Oct. 25, 2017 (CN) 201721386957.X

(51) Int. Cl. H02S 50/15

(52) U.S. Cl. CPC H02S 50/15

(57) ABSTRACT

Provided are a device and method for detecting a photovoltaic module. An exemplary device for detecting a photovoltaic module may comprise a light source and a projection display unit provided on opposite sides of a photovoltaic module to be detected, respectively. Further, the projection display unit may be configured to display a projection of the photovoltaic module to be detected, generated under illumination of the light source. In devices and methods for detecting a photovoltaic module provided by embodiments herein, under illumination of the light source, the projection of the photovoltaic module to be detected may be displayed on the projection display unit, and bent corner(s) of the photovoltaic module to be detected can also be clearly displayed, which enables an accurate and quick selection of defective photovoltaic modules. Moreover, the removal of the defective photovoltaic modules greatly increases production yield of final products assembled from the photovoltaic modules.

### CROSS REFERENCE TO RELATED APPLICATIONS

This application is a 371 U.S. National Phase of International application No. PCT/CN2018/094946, filed Jul. 9, 2018, and claims benefit/priority of Chinese patent application No. 201721386957.X, filed Oct. 25, 2017, the contents of all of which are incorporated herein by reference in entirety.

### TECHNICAL FIELD

The present disclosure relates to the field of photovoltaic battery processing, and particularly to a device and method for detecting a photovoltaic module.

### BACKGROUND ART

With the continuous development of CIGS (thin-film solar cell CuInxGa(1-x)Se2) thin-film solar cell technology, its application range is broader and broader. CIGS can be deposited on a stainless steel substrate so as to be packaged into a flexible component, and it has characteristics of light weight and being bendable. However, there are many difficulties in practical production of the CIGS thin-film solar cells. The thickness of stainless steel substrate, on which the CIGS is deposited, is only 50 μm, and the total thickness after coating is still less than 55 μm. After large-area coating is completed, no matter during the process of subsequent cutting or vacuum packaging or transportation, it is very easy to cause the corners to bend. However, such bending is extremely unfavorable to the component, especially to a flexible component, because all packaging materials of the component are polymer plastic and have very small thickness and thus would be easily pierced by the bent corner(s) of the battery piece, resulting in failures of subsequent wet leakage current test and reliability test, which greatly reduces the production yield of the components and increases the risk in use of the component. Therefore, finding and picking out the battery pieces with bent corners prior to packaging and lamination can greatly reduce the defective rate of production. In actual production, the battery pieces need to experience a series welding process (i.e. connected in series) before packaging, however, the series welding process may also cause new corner bends. Therefore, the inspection on a battery piece after the series welding is particularly important.

At present, there are two methods for detecting battery piece. One method is to observe the corners of the battery piece with the naked eyes to see if there is a bend, in which way it is difficult to find a battery piece slightly bent and the inspection speed is extremely slow, which greatly reduces the production efficiency. The second method is to touch the two sides of the battery piece with fingers, in which way a slight bend can be found, but only the battery bent upwards can be found, and the sharp corners are easy to scratch the fingers, which threatens the workers' personal safety.

### SUMMARY OF THE DISCLOSURE

The objective of the present disclosure includes providing a device and method for detecting a photovoltaic module, to alleviate at least one of the above problems. It is able to quickly check the defective bent battery and ensure the safety of the operator.

An embodiment of the present disclosure provides a device for detecting a photovoltaic module. The device for detecting a photovoltaic module includes:
a light source and a projection display unit, specifically, the light source and the projection display unit are provided on opposite sides of a photovoltaic module to be detected, respectively, and the projection display unit is configured to display a projection of the photovoltaic module to be detected which is generated under illumination of the light source.

In an embodiment of the present disclosure, the projection display unit includes a blackboard.

In an embodiment of the present disclosure, the projection display unit includes a projection screen.

In an embodiment of the present disclosure, the projection display unit includes a display screen.

In an embodiment of the present disclosure, the light source is a linear light source.

In an embodiment of the present disclosure, a convex lens is provided at a light emission side of the light source.

In an embodiment of the present disclosure, the light source includes a plurality of light emitting diode (LED) light bars, and light emitted from the plurality of LED light bars is parallel light.

In an embodiment of the present disclosure, the light source further includes a lampshade. The lampshade is mounted on outside of the plurality of LED light bars, and light emitted from the light source is perpendicular to the photovoltaic module to be detected.

In an embodiment of the present disclosure, the device for detecting a photovoltaic module further includes a detection platform. The detection platform is light-transmissive and configured to support the photovoltaic module to be detected. The light source is located below the detection platform; and the projection display unit is located above the detection platform.

In an embodiment of the present disclosure, the detection platform includes a tabletop of ultra-white tempered glass, and a plurality of legs configured to support the tabletop.

In an embodiment of the present disclosure, each of the legs is provided with a roller and a locking mechanism configured to lock the roller.

In an embodiment of the present disclosure, the device for detecting a photovoltaic module further includes a positioning unit. The positioning unit is provided on the detection platform and configured to fix the photovoltaic module to be detected.

In an embodiment of the present disclosure, the positioning unit includes a positioning clip.

In an embodiment of the present disclosure, the device for detecting a photovoltaic module further includes a conveying unit. The conveying unit is configured to convey the photovoltaic module to be detected to the detection platform.

In an embodiment of the present disclosure, the device for detecting a photovoltaic module further includes a sensor and a controller. Each of the sensor and the conveying unit is connected with the controller; and the sensor is provided on the detection platform and configured to sense position of the photovoltaic module to be detected.

In an embodiment of the present disclosure, the sensor is configured to send to the controller a position signal which is obtained by sensing a position of the photovoltaic module to be detected; and the controller is configured to adjust a working state of the conveying unit according to the position signal, the working state includes a moving state and a stop state.

In an embodiment of the present disclosure, the conveying unit includes a motor and a conveying belt; the photovoltaic module to be detected is placed on the conveying belt; and the motor is configured to drive the conveying belt for delivery.

An embodiment of the present disclosure further provides a method for detecting a photovoltaic module, applicable to the devices for detecting a photovoltaic module. The method includes the steps of:
illuminating, by the light source of the device for detecting a photovoltaic module, the photovoltaic module to be detected;
displaying, by the projection display unit of the device for detecting a photovoltaic module, the projection of the photovoltaic module to be detected which is generated under illumination of the light source;
determining, according to the projection, whether the photovoltaic module to be detected is bent.

The device and method for detecting a photovoltaic module provided by embodiments of the present disclosure, under the illumination of the light source, displays the projection of the photovoltaic module to be detected on the projection display unit; the projection corresponding to the photovoltaic module to be detected with bending corner(s) will show the bright spot or bright dot, which enables the accurate and quick selection of the defective photovoltaic module. The optical detecting method adopted in embodiments of the present disclosure can increase the convenience of the nondestructive detection on the corner bending of the photovoltaic module to be detected, have a high detecting accuracy and a high detecting speed, and can perform an accurate detecting on both upward and downward bending conditions, and also ensure the safety of the operator. In addition, the removal of the defective photovoltaic module(s) greatly increases the production yield of the final products assembled from the photovoltaic modules, reduces the loss caused by the defective scrap, reduces the safety hazards in use of the product, and reduces the customer's complaints about the reliability and service life problems.

### BRIEF DESCRIPTION OF THE DRAWINGS

FIG. 1 is a schematic structural diagram of a device for detecting a photovoltaic module provided by an embodiment of the present disclosure;

FIG. 2 is a flow chart of a method for detecting a photovoltaic module provided by an embodiment of the present disclosure.

FIG. 3 is a flow chart of a method for detecting a photovoltaic module provided by an embodiment of the present disclosure.

### DESCRIPTION OF THE REFERENCE NUMERALS

1—Light source, 11—LED light bar, 12—lampshade, 2—detection platform, 21—tabletop, 22—leg, 3—projection display unit, 4—photovoltaic module to be detected; 5—convex lens; 6—roller; 7—locking mechanism; 8—positioning unit; 9—conveying unit; 91—conveying belt; 92—motor; 100—controller; 110—sensor.

### DETAILED DESCRIPTION OF THE EMBODIMENTS

The embodiments of the present disclosure are described in detail below, and examples of the embodiments are shown in the drawings. The same or similar reference numerals refer to same or similar elements or elements having same or similar functions throughout the context. The embodiments described below with reference to the drawings are illustrative and only used to explain the present disclosure, and cannot be construed as limiting the present disclosure.

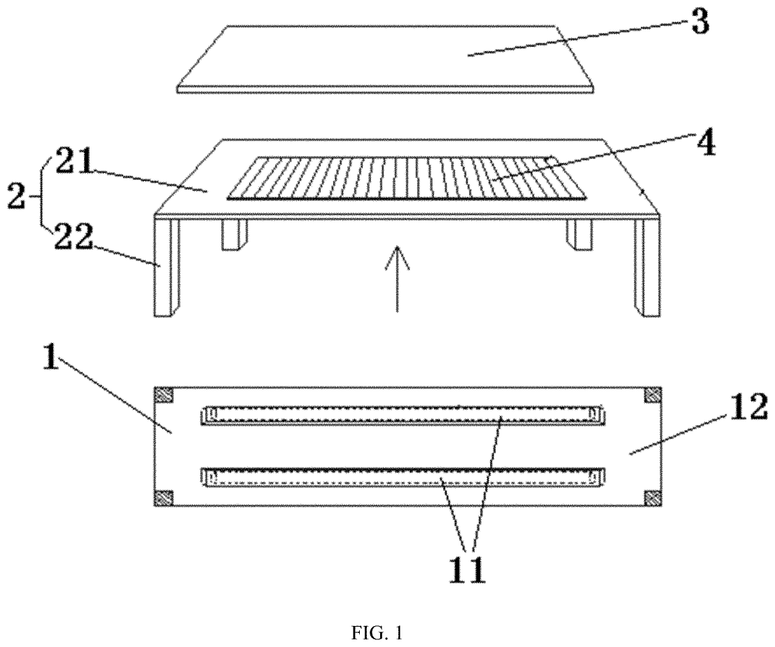

As shown in FIG. 1, an embodiment of the present disclosure provides a device for detecting a photovoltaic module. The device for detecting a photovoltaic module includes: a light source 1 and a projection display unit 3. The light source 1 and the projection display unit 3 are provided on opposite sides of a photovoltaic module to be detected 4, respectively, and the projection display unit 3 is configured to display a projection of the photovoltaic module to be detected 4 which is generated under illumination of the light source 1. Specifically, the photovoltaic module to be detected may include one or more battery pieces.

The device for detecting a photovoltaic module provided in an embodiment of the present disclosure displays, by the illumination of the light source 1, the projection of the photovoltaic module to be detected 4 on the projection display unit 3. In this way, the projection of bending corner region of the photovoltaic module to be detected 4 is displayed to be abnormal, and the projected image may be amplified, so that an operator can accurately and quickly identify the condition of the bending corner and then pick out the defective photovoltaic module. An optical detecting method adopted in an embodiment of the present disclosure can increase the convenience of the nondestructive detection on the corner bending of the photovoltaic module to be detected, have a high detecting accuracy and a high detecting speed, can perform an accurate detection on both upward and downward bending conditions, and also ensure the safety of the operator. In addition, the removal of the defective photovoltaic module(s) greatly increases the production yield of the final products assembled from the photovoltaic modules, reduces the loss caused by the defective scrap, reduces the safety hazards in use of the product, and reduces the customer's complaints about the reliability and service life problems.

In order to prevent external natural light from interfering with the detecting light and affecting the determination on the bright spot or bright dot, the entire detecting device needs to be placed in a dark box or a dark room during the detecting process.

In an embodiment of the present disclosure, the projection display unit 3 includes a blackboard. The projection display unit 3 may be implemented in various ways, such as a projection screen and a display screen.

In an embodiment of the present disclosure, the light source 1 may be a linear light source, that is, the light source 1 may be an elongated light source, and the number of the light sources may be one or more.

In an embodiment of the present disclosure, the light source 1 includes a plurality of LED light bars 11, and the light emitted from the plurality of LED light bars 11 is parallel light. Ordinary light sources 1 may also be adopted, such as incandescent lamps and energy-saving lamps. The color of the light emitted from the abovementioned light source may be white or other color, which will not be elaborated here.

In an embodiment of the present disclosure, the light source 1 further includes a lampshade 12. The lampshade 12 is mounted on outside of the plurality of LED light bars 11, and the light emitted from the light source is perpendicular to the photovoltaic module to be detected 4.

Specifically, the function of the lampshade 12 is to effectively use the light source 1, increase the brightness and cause the direction of illumination of the light source 1 to be vertically upward, that is, the light emitted, after passing through the lampshade 12, from the LED light bar 11 is parallel light, and that the light emitted from the light source 1 is perpendicular to the photovoltaic module to be detected 4, such that the projection of the photovoltaic module to be detected 4 can be accurately displayed on the projection display unit 3, which is convenient for the operator to perform the inspection. The function of the blackboard is to better observe the high-definition projection, which improves the accuracy of the visibility and determination.

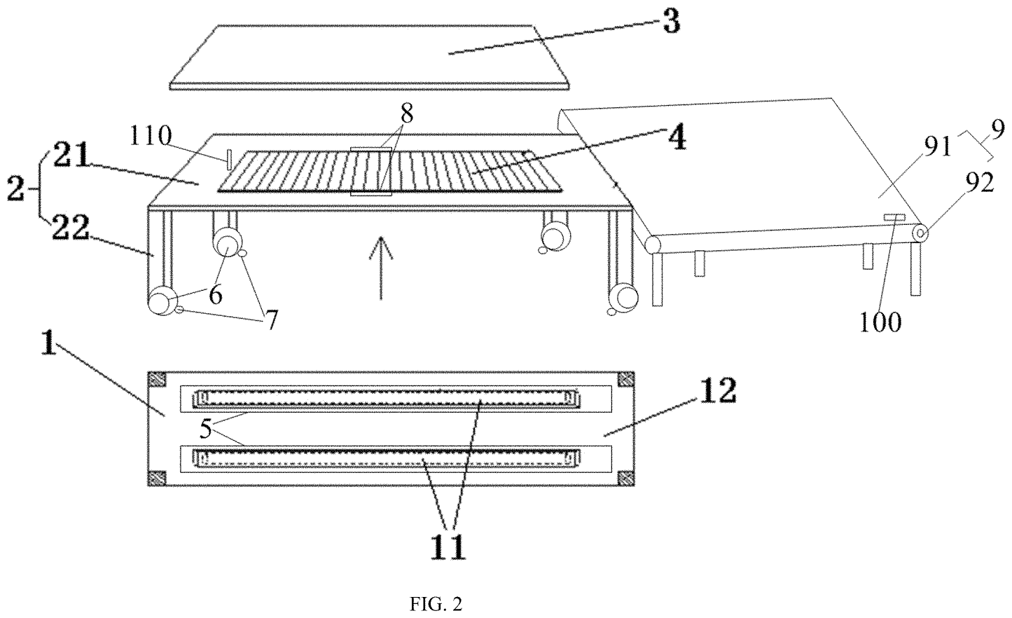

In an embodiment of the present disclosure, in order to cause the light emitted from the light source 1 to be in the upward vertical direction, as shown in FIG. 2, a convex lens 5 may be provided at a light emission side of the light source such as a light bar.

In an embodiment of the present disclosure, the device for detecting a photovoltaic module further includes a detection platform 2, with the detection platform being light-transmissive and configured to support the photovoltaic module to be detected 4. The light source 1 is located below the detection platform 2, and the projection display unit 3 is located above the detection platform 2. The projection display unit 3 may be hung within a dark box or in the top of the dark box. The height of the hung projection display unit may be set to be adjustable. Of course, the projection display unit 3 may also be supported by a bracket installed at bottom of the dark box or the dark room and the height of the bracket can be set to be adjustable.

In an embodiment of the present disclosure, the detection platform 2 includes a tabletop 21 of ultra-white tempered glass and a plurality of legs 22. The plurality of legs are configured to support the tabletop 21.

In order to facilitate the movement of the detection platform 2, as shown in FIG. 2, each of the plurality of legs may be provided with a roller 6 and a locking mechanism 7, with the locking mechanism configured to lock the roller 6. The locking mechanism 7 is also referred to as a roller locking mechanism. In FIG. 2, the locking mechanism 7 is only simply illustrated, which should not be considered as a limitation. In actual application, other mechanisms capable of locking the roller may also be adopted.

Specifically, the light source 1 is installed below the detection platform 2 and mainly provides a high-brightness parallel light for detecting the photovoltaic module to be detected 4. When the light passes through, in the upward direction, the detection platform 2 to illuminate the edge(s) of the photovoltaic module to be detected 4, the projection of the edge(s) of the photovoltaic module to be detected 4 appears on the blackboard above the detection platform 2, while the projection corresponding to the photovoltaic module to be detected 4 with bending corner(s) will show the bright spot or bright dot. In this way, the photovoltaic module to be detected 4 can be easily found according to the position of the bright dots and is replaced manually or mechanically.

In an embodiment of the present disclosure, the device for detecting a photovoltaic module further includes a positioning unit 8. The positioning unit 8 is provided on the detection platform 2 and configured to fix the photovoltaic module to be detected 4. In an embodiment of the present disclosure, the device for detecting a photovoltaic module also includes a conveying unit 9. The conveying unit is configured to convey the photovoltaic module to be detected 4 to the detection platform 2.

In an embodiment of the present disclosure, the device for detecting a photovoltaic module further includes a sensor 110 and a controller 100. Each of the sensor 110 and the conveying unit 9 is connected with the controller 100. The sensor 110 is provided on the detection platform 2 and configured to sense the position of the photovoltaic module to be detected 4. Specifically, the sensor 110 may be an infrared range sensor or an ultrasonic range sensor or the like. Specifically, the sensor 110 and the conveying unit 9 may be connected with the controller 100 through a wire, or may be communicated and connected with the controller 100 in a wireless way. Therefore, in FIG. 2, the controller 100 is only illustrated separately, and the wired connections between the controller 100 and each of the sensor 110 and the conveying unit 9 are not explicitly illustrated.

In actual application, the sensor mentioned above may be configured to send a position signal, obtained by sensing the position of the photovoltaic module to be detected, to the controller; the controller may be configured to adjust the working state of the conveying unit according to the position signal; and the working state includes a moving state and a stop state. For example, the controller may determine, according to the position signal sent by the sensor, whether the photovoltaic module to be detected is delivered to a specific position of the detection platform by the conveying unit. If the photovoltaic module to be detected is delivered to a specific position, the controller adjusts the conveying unit from a moving state to a stop state; if the photovoltaic module to be detected is not delivered to a specific position, the controller continues making the conveying unit keep being in the moving state, until the photovoltaic module to be detected is delivered to a specific position of the detection platform.

In an embodiment of the present disclosure, the controller 100 is also connected with the positioning unit 8, the connection may be a wired connection or a wireless communication connection. In an embodiment of the present disclosure, the conveying unit 9 includes a motor 92 and a conveying belt 91. The photovoltaic module to be detected 4 is placed on the conveying belt 91, and the motor 92 is configured to drive the conveying belt to deliver.

Specifically, in the embodiment of the present disclosure, the motor 92 may be controlled by the controller 100 to drive the conveying belt 91. When the sensor 110 detects that the photovoltaic module to be detected 4 arrives at an appropriate position, the sensor sends a signal to the controller 100, and the controller 100 controls the motor 92 to stop conveying and at the same time controls the positioning unit 8 to fix the photovoltaic module to be detected 4. The positioning unit 8 may achieve positioning structures in various ways such as a positioning clip or a structure, configured to block, at both ends of the photovoltaic module to be detected 4.

Based on various implementations of the above mentioned device for detecting a photovoltaic module, the specific implementation of a simple and practical device for detecting a photovoltaic module is described in detail herein with respect to FIG. 1. As shown in FIG. 1, the photovoltaic module to be detected 4 is placed on the detection platform 2 consisted of the tabletop 21 and the leg(s) 22. The tabletop 21 is a horizontal tabletop and the area of the tabletop is larger than the area of the photovoltaic module to be detected 4, so as to horizontally place the photovoltaic module to be detected 4 better. As also shown in FIG. 1, the number of the legs 22 is four, and the legs are respectively placed at the four corners of the tabletop 21 to achieve the effect of stably supporting the tabletop 21. The height of the legs 22 can be set flexibly, though not particularly restrictive herein. FIG. 1 also shows a light source 1 consisted of two parallel LED light bars 11 and a lampshade 12; the lampshade 12 is mounted on outside of the two LED light bars 11. When installing the light source of the device for detecting a photovoltaic module, the light emitted from the LED light bar 11, after passing through the lampshade 12, needs to be perpendicular to the photovoltaic module to be detected 4. The light source 1 is provided on one side of the photovoltaic module to be detected 4, and the projection display unit 3 is provided on the other side of the photovoltaic module to be detected 4. As shown in FIG. 1, the light source 1 is provided on the lower side of the photovoltaic module to be detected 4, and the projection display unit 3 is provided on the upper side of the photovoltaic module to be detected 4, all of which are at a certain distance from the photovoltaic module to be detected 4. The projection display unit may display the projection of the photovoltaic module to be detected 4 which is generated under illumination of the light source 1.

It should be noted that the above is only a simple embodiment of a device for detecting a photovoltaic module. In actual application, the embodiment described in FIG. 1 should not be regarded as a limitation, and the structure of the device for detecting a photovoltaic module can be flexibly adjusted according to demands, for example the form of the detection platform may not be limited to a rectangular supporting tabletop with four legs; and the form of the supporting tabletop, the number of the legs may also be flexibly set. In addition, the detection platform for supporting the photovoltaic module to be detected may not be provided, and the photovoltaic module to be detected may be fixed by other means such as a securing slot, as long as the light source and the projection display unit are respectively located on opposite sides of the photovoltaic module to be detected and the projection display unit can display the projection of the photovoltaic module to be detected which is generated under illumination of the light source. In addition, if the positions of the light source and the projection display unit are fixed, the device for detecting a photovoltaic module may further include, for example, a conveying unit (a conveying belt and a motor) for conveying the photovoltaic module to be detected, such that the conveying unit can convey the photovoltaic module to be detected to a designated region between the light source and the projection display unit. The designated region is the position for detecting the photovoltaic module to be detected. Furthermore, an inductor such as a position sensor may also be provided to sense the position of the photovoltaic module to be detected, so as to ensure that the photovoltaic module to be detected is located in the designated region.

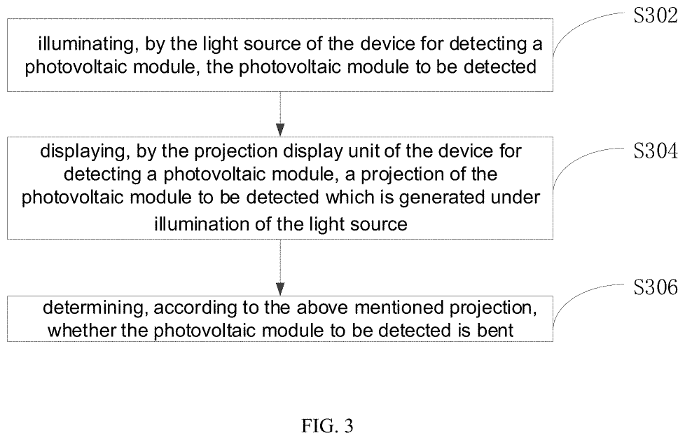

Based on the above mentioned device for detecting a photovoltaic module, an embodiment of the present disclosure also provides a method for detecting a photovoltaic module. The method is applicable to any one of the above mentioned devices for detecting a photovoltaic module. Referring to a flow chart of a method for detecting a photovoltaic module shown in FIG. 3, the method includes the steps of:

Step S302: illuminating, by the light source of the device for detecting a photovoltaic module, the photovoltaic module to be detected;

Step S304: displaying, by the projection display unit of the device for detecting a photovoltaic module, a projection of the photovoltaic module to be detected which is generated under illumination of the light source.

Step S306: determining, according to the above mentioned projection, whether the photovoltaic module to be detected is bent.

In an embodiment, the projection of a normal photovoltaic module (i.e. an unbent photovoltaic module) may be predetermined, and if the projection of the photovoltaic module to be detected is different from the projection of the normal photovoltaic module, it is indicated that the photovoltaic module to be detected is bent. In another embodiment, the projection of a bent photovoltaic module may be predetermined, and if the projection of the photovoltaic module to be detected coincides with the projection of the bent photovoltaic module, it is indicated that the photovoltaic module to be detected is bent.

The method for detecting a photovoltaic module provided by an embodiment of the present disclosure, under the illumination of the light source, displays the projection of the photovoltaic module to be detected on the projection display unit; the projection of the bending corner region of the photovoltaic module to be detected is displayed to be abnormal, and the projected image may be amplified, so that an operator can accurately and quickly identify the condition of the bending corner and then pick out the defective photovoltaic module. The optical detecting method adopted in embodiment of the present disclosure can increase the convenience of the nondestructive detection on the corner bending of the photovoltaic module to be detected, have a high detecting accuracy and a high detecting speed, can perform an accurate detecting on both upward and downward bending conditions, and also ensure the safety of the operator. In addition, the removal of the defective photovoltaic module(s) greatly increases the production yield of the final products assembled from the photovoltaic modules, reduces the loss caused by the defective scrap, reduces the safety hazards in use of the product, and reduces the customer's complaints about the reliability and service life problems. The structure, features, and effects of the present disclosure are described in detail based on the above embodiments shown in the drawings. The above description is only the preferred embodiments of the present disclosure. However, the present disclosure does not limit the scope of implementation by what has been shown in the drawings. Any changes made according to the concept of the present disclosure, or any equivalent embodiment that have been modified with equal changes, are still within the scope of protection of the present disclosure if they do not depart from the spirit within the specification and drawings.

### INDUSTRIAL APPLICABILITY

By applying the technical solution of the present disclosure, the convenience of the nondestructive detection on the corner bending of the photovoltaic module to be detected may be increased, with high detecting accuracy, high detecting speed, and accurate detecting of both upward and downward bending conditions can be performed, and the safety of the operator is also ensured. In addition, the removal of the defective photovoltaic module(s) greatly increases the production yield of the final products assembled from the photovoltaic modules, reduces the loss caused by the defective scrap, reduces the safety hazards in use of the product, and reduces the customer's complaint about the reliability and service life problems.

1. A device for detecting a photovoltaic module, comprising:
a light source and a projection display unit, wherein the light source and the projection display unit are provided on opposite sides of a photovoltaic module to be detected, respectively, and the projection display unit is configured to display a projection of the photovoltaic module to be detected which is generated under illumination of the light source.

2. The device for detecting a photovoltaic module according to claim 1, wherein the projection display unit comprises a blackboard.

3. The device for detecting a photovoltaic module according to claim 1, wherein the projection display unit comprises a projection screen.

4. The device for detecting a photovoltaic module according to claim 1, wherein the projection display unit comprises a display screen.

5. The device for detecting a photovoltaic module according to claim 1, wherein the light source is a linear light source.

6. The device for detecting a photovoltaic module according to claim 5, wherein a convex lens is provided at a light emission side of the light source.

7. The device for detecting a photovoltaic module according to claim 5, wherein the light source comprises a plurality of light emitting diode (LED) light bars, and light emitted from the plurality of LED light bars is parallel light.

8. The device for detecting a photovoltaic module according to claim 7, wherein the light source further comprises a lampshade, the lampshade is mounted on outside of the plurality of LED light bars, and light emitted from the light source is perpendicular to the photovoltaic module to be detected.

9. The device for detecting a photovoltaic module according to claim 1, further comprising a detection platform, wherein the detection platform is light-transmissive and configured to support the photovoltaic module to be detected; the light source is located below the detection platform; and the projection display unit is located above the detection platform.

10. The device for detecting a photovoltaic module according to claim 9, wherein the detection platform comprises a tabletop of ultra-white tempered glass, and a plurality of legs configured to support the tabletop.

11. The device for detecting a photovoltaic module according to claim 10, wherein each of the plurality of legs is provided with a roller and a locking mechanism configured to lock the roller.

12. The device for detecting a photovoltaic module according to claim 9, further comprising a positioning unit, wherein the positioning unit is provided on the detection platform and configured to fix the photovoltaic module to be detected.

13. The device for detecting a photovoltaic module according to claim 12, wherein the positioning unit comprises a positioning clip.

14. The device for detecting a photovoltaic module according to claim 12, further comprising a conveying unit, configured to convey the photovoltaic module to be detected to the detection platform.

15. The device for detecting a photovoltaic module according to claim 14, further comprising a sensor and a controller; wherein each of the sensor and the conveying unit is connected with the controller; and the sensor is provided on the detection platform and configured to sense a position of the photovoltaic module to be detected.

16. The device for detecting a photovoltaic module according to claim 15, wherein the sensor is configured to send to the controller a position signal which is obtained by sensing a position of the photovoltaic module to be detected; and the controller is configured to adjust a working state of the conveying unit according to the position signal, the working state comprising a moving state and a stop state.

17. The device for detecting a photovoltaic module according to claim 14, wherein the conveying unit comprises a motor and a conveying belt; the photovoltaic module to be detected is placed on the conveying belt, and the motor is configured to drive the conveying belt for delivery.

18. A method for detecting a photovoltaic module, applicable to the devices for detecting a photovoltaic module according to claim 1, comprising steps of:
illuminating, by the light source of the device for detecting a photovoltaic module, the photovoltaic module to be detected;
displaying, by the projection display unit of the device for detecting a photovoltaic module, a projection of the photovoltaic module to be detected which is generated under illumination of the light source;
determining, according to the projection, whether the photovoltaic module to be detected is bent.

19. The device for detecting a photovoltaic module according to claim 6, wherein the light source comprises a plurality of light emitting diode (LED) light bars, and light emitted from the plurality of LED light bars is parallel light.

20. The device for detecting a photovoltaic module according to claim 2, further comprising a detection platform, wherein the detection platform is light-transmissive and configured to support the photovoltaic module to be detected; the light source is located below the detection platform; and the projection display unit is located above the detection platform.
